(19) United States
(12) Patent Application Publication
(10) Pub. No.: US 2026/0333709 A1
(43) Pub. Date: Oct. 22, 2026

(54) MAGNETORESISTIVE ELEMENT AND MAGNETIC MEMORY

(71) Applicant: TDK Corporation, Tokyo (JP)

(72) Inventors: Zhenyao TANG, Tokyo (JP); Tomoyuki SASAKI, Tokyo (JP)

(73) Assignee: TDK Corporation, Tokyo (JP)

(21) Appl. No.: 18/704,779

(22) PCT Filed: Sep. 29, 2023
(86) PCT No.: PCT/JP2023/035805

§ 371 Date: Apr. 25, 2024

(51) Int. Cl. H10B 61/00; H10N 50/10

(52) U.S. Cl. CPC H10B 61/10; H10N 50/10

(57) ABSTRACT

A magnetoresistive element includes a substrate, a base layer provided on the substrate, and a stacked portion provided on the base layer and including a magnetization free layer, a reference layer, and a nonmagnetic layer provided between the magnetization free layer and the reference layer. The base layer includes two or more metal nitride layers and a metal oxynitride layer provided between a first metal nitride layer and a second metal nitride layer among the two or more metal nitride layers.

### TECHNICAL FIELD

The present disclosure relates to a magnetoresistive element and a magnetic memory.

### BACKGROUND ART

A magnetoresistive element such as a giant magnetoresistive (GMR) element and a tunnel magnetoresistive (TMR) element having a stacked body in which a magnetization free layer made of a ferromagnetic substance, a nonmagnetic spacer layer, and a reference layer (fixed layer) made of a ferromagnetic substance are stacked in this order is being developed as an element for devices such as a magnetic field sensor, a magnetic head, and a magnetic random access memory (MRAM).

### CITATION LIST

### Non Patent Literature

Non Patent Literature 1: S. Yuasa et al. Nature Materials 3, 868-871,2004
Non Patent Literature 2: J. Slonczewski: J. Magn. Magn. Mater. 159 (1996) L1
Non Patent Literature 3: S. Takahashi and S. Maekawa, Phys. Rev. Lett. 80, 1758(1998)

### SUMMARY OF INVENTION

### Technical Problem

In the device such as the MRAM using the magnetoresistive element described above, it is desirable to increase flatness and crystallinity of a layer constituting the magnetoresistive element from the viewpoint of reliability related to a lifespan of the device and the like.

The present disclosure has been made in view of the above-described problems, and an object thereof is to provide a magnetoresistive element having high flatness and crystallinity of layers constituting an element, and a magnetic memory using such a magnetoresistive element.

### Solution to Problem

In order to solve the above problems, a magnetoresistive element according to the present disclosure includes a substrate, a base layer provided on the substrate, a stacked portion provided on the base layer and including a magnetization free layer, a reference layer, and a nonmagnetic layer provided between the magnetization free layer and the reference layer. The base layer includes two or more metal nitride layers and a metal oxynitride layer provided between a first metal nitride layer and a second metal nitride layer of the two or more metal nitride layers.

In the magnetoresistive element according to the present disclosure, since there are at least three layers in the base layer, there are at least two interfaces between two layers made of different materials. Thus, when the base layer is formed, since a layer formed on the interface is easily crystallized, crystallinity and flatness of an uppermost layer of the two or more metal nitride layers of the base layer are improved as compared with a case where the entire base layer 1 is formed only of a material constituting the uppermost layer. Thus, crystallinity and flatness of layers constituting the stacked portion formed on the base layer can be improved.

Further, in the magnetoresistive element according to the present disclosure, a metal constituting the first metal nitride layer may be different from a metal constituting the second metal nitride layer. In this case, since the at least two interfaces are formed by a combination of layers different from each other, the effect of improving the crystallinity and flatness of the layers constituting the stacked portion due to the presence of at least two interfaces is more effectively exhibited.

Further, the magnetoresistive element according to the present disclosure may further include a metal layer provided between the base layer and the stacked portion. In this case, the metal layer can further improve the crystallinity and flatness of the layers constituting the stacked portion formed thereon.

Further, in the magnetoresistive element according to the present disclosure, the reference layer may include a first ferromagnetic layer, a second ferromagnetic layer, and a nonmagnetic insertion layer provided between the first ferromagnetic layer and the second ferromagnetic layer such that the first ferromagnetic layer and the second ferromagnetic layer are exchange-coupled. In this case, a magnetization direction of the reference layer can be further stabilized.

Further, in the magnetoresistive element according to the present disclosure, the first metal nitride layer may be provided on a side of the metal oxynitride layer close to the substrate, the second metal nitride layer may be provided on a side of the metal oxynitride layer close to the stacked portion, and the first metal nitride layer may be thickest in the base layer. In this case, at least one position of the at least two interfaces of the base layer is close to the stacked portion. Thus, the above effect of improving the crystallinity and flatness of the layers constituting the stacked portion due to the presence of at least two interfaces is more effectively exhibited.

Further, in the magnetoresistive element according to the present disclosure, the base layer may further include a third metal nitride layer as the two or more metal nitride layers, and a metal nitride layer positioned in the middle in a thickness direction of the base layer, among the first metal nitride layer, the second metal nitride layer, and the third metal nitride layer, may be thickest.

Further, in the magnetoresistive element according to the present disclosure, a metal nitride layer provided closest to the substrate of the two or more metal nitride layers can be thicker than the metal oxynitride layer. In this case, the positions of the at least two interfaces of the base layer are close to the stacked portion. Thus, the above effect of improving the crystallinity and flatness of the layers constituting the stacked portion due to the presence of at least two interfaces is more effectively exhibited.

Further, in the magnetoresistive element according to the present disclosure, a metal constituting the metal nitride layer closest to the stacked portion of the two or more metal nitride layers and a metal constituting the metal nitride layer closest to the substrate of the two or more metal nitride layers may be the same.

Further, in the magnetoresistive element according to the present disclosure, a thickness of the base layer may be 50 nm or more.

In addition, a magnetic memory according to the present disclosure includes a plurality of any of the magnetoresistive elements described above.

### Advantageous Effects of Invention

In accordance with the present disclosure, the magnetoresistive element having high flatness and crystallinity of the layers constituting the element, and the magnetic memory using such a magnetoresistive element are provided.

### BRIEF DESCRIPTION OF DRAWINGS

FIG. 1 is a diagram illustrating a longitudinal sectional structure of a magnetoresistive element according to an embodiment.

FIG. 2 is a diagram illustrating a detailed longitudinal sectional structure of a base layer and a metal layer.

FIG. 3 is a diagram illustrating a detailed longitudinal sectional structure of a base layer and a metal layer of a TMR element according to a modification of the embodiment.

FIG. 4 is a longitudinal sectional view of a TMR element 30.

FIG. 5 is a diagram illustrating a circuit diagram of a magnetic memory 100.

### DESCRIPTION OF EMBODIMENTS

Hereinafter, an embodiment of the present disclosure will be described in detail with reference to the accompanying drawings. Note that, in the drawings, the same reference signs are used for the same elements as possible. In addition, dimensional ratios within components and between components in the drawings are any dimensional ratios for ease of viewing of the drawings.

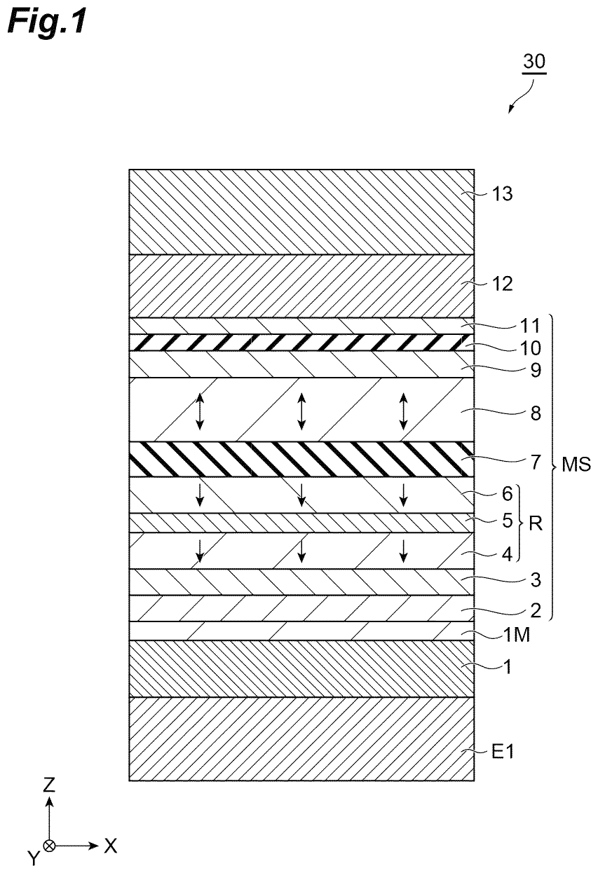

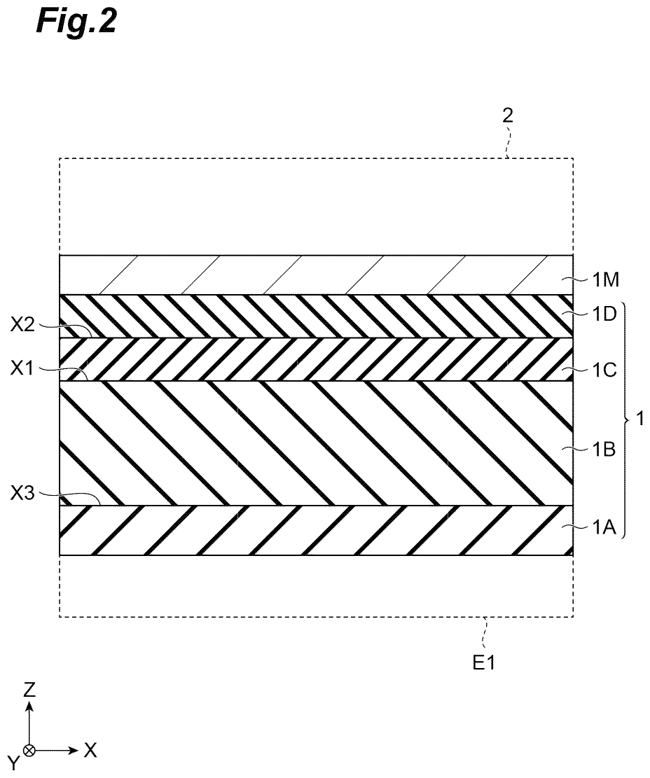

FIG. 1 is a diagram illustrating a longitudinal sectional structure of a magnetoresistive element according to the present embodiment. The magnetoresistive element of the present embodiment is a tunnel magnetoresistive (TMR) element 30. As illustrated in FIG. 1, the TMR element 30 includes a substrate E1 functioning as an electrode, a base layer 1 provided on the substrate E1, a metal layer 1M provided on the base layer 1, a stacked portion MS provided on the metal layer 1M, and electrode layers 12 and 13 provided on the stacked portion MS. FIG. 1 illustrates an orthogonal coordinate system in which a Z-axis is set in a stacking direction of the layers of the TMR element 30 and an X-axis and a Y-axis are set in an in-plane direction of the layers of the TMR element 30. In FIG. 2 and subsequent drawings, the orthogonal coordinate system is illustrated as necessary to correspond to FIG. 1.

The substrate E1 functioning as the electrode is made of a nonmagnetic metal such as Al, Cu, or Ta. The metal layer 1M is made of a metal material such as Mg or Fe, and is provided for the purpose of, for example, improving crystallinity of the upper layers. The TMR element 30 may not include the metal layer 1M.

The stacked portion MS includes a first buffer layer 2 made of a metal such as Fe or Cr, a second buffer layer 3 made of an alloy such as NiCr, a reference layer R, a tunnel barrier layer 7 as a nonmagnetic layer, a magnetization free layer 8, a first cap layer 9, an intermediate layer 10, and a second cap layer 11.

The reference layer R includes a first ferromagnetic layer 4, a nonmagnetic insertion layer 5, and a second ferromagnetic layer 6. The first ferromagnetic layer 4 is made of a ferromagnetic material such as CoNi. The nonmagnetic insertion layer 5 is made of a nonmagnetic material such as Ir or Mo. The second ferromagnetic layer 6 is made of a ferromagnetic material such as CoFeB. The nonmagnetic insertion layer 5 is provided between the first ferromagnetic layer 4 and the second ferromagnetic layer 6 such that the first ferromagnetic layer and the second ferromagnetic layer are exchange-coupled. As a result, magnetization of the first ferromagnetic layer 4 and a magnetization direction of the second ferromagnetic layer 6 indicated by arrows in FIG. 1 are coupled so as to be parallel to each other.

The tunnel barrier layer 7 is provided between the reference layer R and the magnetization free layer 8. The tunnel barrier layer 7 allows electrons to pass by using a tunnel effect. The tunnel barrier layer 7 is made of at least one material selected from the group consisting of, for example, MgO, Al₂O₃, ZnO, GaOX, and MgAl₂O₄. The magnetization free layer 8 is made of, for example, a ferromagnetic material containing Co or a ferromagnetic material containing at least two elements selected from the group consisting of Co, Ni, Fe, and B, and is made of, for example, CoFeB. A magnetization direction of the magnetization free layer 8 indicated by an arrow in FIG. 1 can be easily changed. In a case where magnetization directions of the reference layer R and the magnetization free layer 8 are parallel, magnetic resistance is low. On the other hand, in a case where these directions are antiparallel, the magnetic resistance is high.

In a case where the tunnel barrier layer 7 is made of a material such as MgO, perpendicular magnetic anisotropy can be imparted to ferromagnetic substances of the reference layer R and the first ferromagnetic layer 4. In this case, as illustrated in FIG. 1, the magnetization directions of the first ferromagnetic layer 4 and the second ferromagnetic layer 6 of the reference layer R are fixed in a direction along the Z-axis, and a magnetization easy axis of the magnetization free layer 8 is the direction along the Z-axis.

The first cap layer 9 is provided on the magnetization free layer 8 and is made of a nonmagnetic material of an oxide such as MgO. A thickness of the first cap layer 9 is smaller than a thickness of the tunnel barrier layer 7. The intermediate layer 10 is a layer containing a ferromagnetic element such as Co or Fe, is made of, for example, an alloy such as CoFe, and is provided to be interposed between the first cap layer 9 and the second cap layer 11. The second cap layer 11 is provided on the intermediate layer 10 and contains at least one element selected from the group consisting of Ru, Mo, and W.

The electrode layer 12 is made of a conductive material, and is made of, for example, a stacked body of Ru/Mo/Ru. The electrode layer 13 is made of a conductive material, and is made of, for example, a metal such as W or Mo.

FIG. 2 is a diagram illustrating a detailed longitudinal sectional structure of the base layer and the metal layer. The base layer 1 has a configuration in which a plurality of layers are stacked in a Z-axis direction, and has three metal nitride layers and one metal oxynitride layer in the present embodiment. Specifically, as illustrated in FIG. 2, the base layer 1 includes a first metal nitride layer 1B, a second metal nitride layer 1D, a metal oxynitride layer 1C provided between the first metal nitride layer 1B and the second metal nitride layer 1D in the Z-axis direction, and a third metal nitride layer 1A provided between the first metal nitride layer 1B and the substrate E1.

The first metal nitride layer 1B is provided on a side of the metal oxynitride layer 1C close to the substrate E1, and the second metal nitride layer 1D is provided on a side of the metal oxynitride layer 1C close to the stacked portion MS (see FIG. 1). The second metal nitride layer 1D is a layer provided closest to the stacked portion MS (see FIG. 1), among the metal nitride layers included in the base layer 1, and the third metal nitride layer 1A is a layer provided closest to the substrate E1 among the metal nitride layers included in the base layer 1.

In the base layer 1, an interface X1 is formed between the first metal nitride layer 1B and the metal oxynitride layer 1C, an interface X2 is formed between the metal oxynitride layer 1C and the second metal nitride layer 1D, and an interface X3 is formed between the third metal nitride layer 1A and the first metal nitride layer 1B.

The base layer 1 is formed by, for example, depositing the third metal nitride layer 1A, the first metal nitride layer 1B, the metal oxynitride layer 1C, and the second metal nitride layer 1D in this order on the substrate E1.

The first metal nitride layer 1B, the second metal nitride layer 1D, and the third metal nitride layer 1A are made of, for example, a metal nitride such as tantalum nitride (TaN) or titanium nitride (TiN). The first metal nitride layer 1B and the third metal nitride layer 1A are made of different metal nitrides. The metal oxynitride layer 1C is made of a metal oxynitride such as titanium oxynitride (TiON) or tantalum oxynitride (TaON).

In the present embodiment, the metal constituting the first metal nitride layer 1B is different from the metal constituting the second metal nitride layer 1D. In addition, in the present embodiment, the metal constituting the second metal nitride layer 1D is the same as the metal constituting the third metal nitride layer 1A. These conditions can be achieved by making, for example, the first metal nitride layer 1B of titanium nitride (TiN), the second metal nitride layer 1D of tantalum nitride (TaN), and the third metal nitride layer 1A of tantalum nitride (TaN).

A thickness of the first metal nitride layer 1B in the Z-axis direction can be, for example, 5 nm or more and 100 nm or less, a thickness of the second metal nitride layer 1D in the Z-axis direction can be, for example, 2 nm or more and 50 nm or less, a thickness of the metal oxynitride layer 1C in the Z-axis direction can be, for example, 2 nm or more and 50 nm or less, and a thickness of the third metal nitride layer 1A in the Z-axis direction can be, for example, 5 nm or more and 50 nm or less.

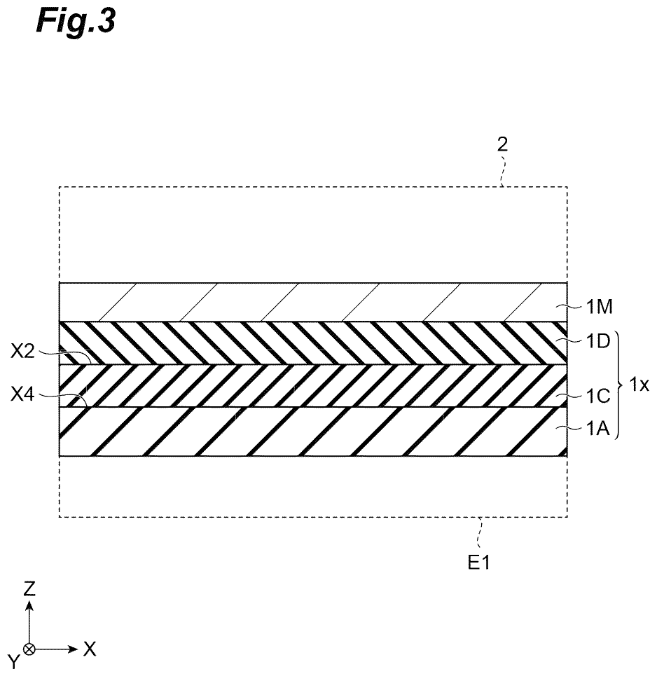

FIG. 3 is a diagram illustrating a detailed longitudinal sectional structure of a base layer and a metal layer of a TMR element according to a modification of the present embodiment. The TMR element of the present modification is different from the TMR element 30 according to the above-described basic embodiment described above in the configuration of the base layer. Specifically, a base layer 1x according to the present modification has a configuration in which the first metal nitride layer 1B is removed from the base layer 1 (see FIG. 2) of the above-described basic embodiment. Thus, in the present modification, the base layer 1x includes two metal nitride layers (second metal nitride layer 1D and third metal nitride layer 1A) and one metal oxynitride layer (metal oxynitride layer 1C).

In the base layer 1x, an interface X4 is formed between the third metal nitride layer 1A and the metal oxynitride layer 1C, and the interface X2 is formed between the metal oxynitride layer 1C and the second metal nitride layer 1D.

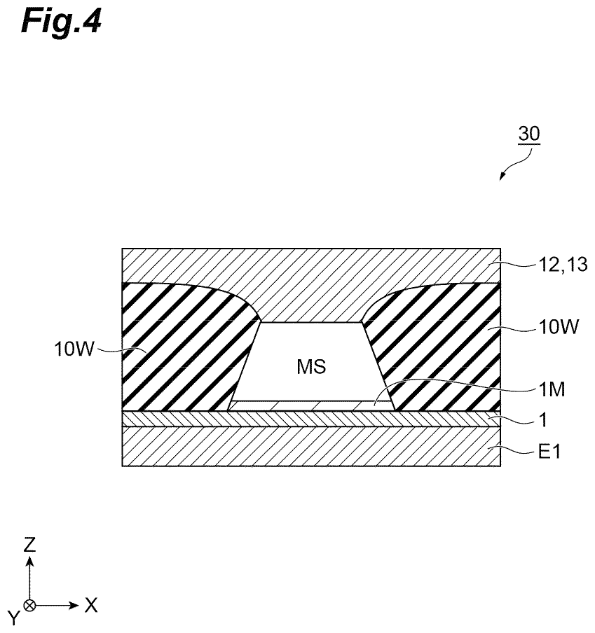

FIG. 4 is a longitudinal sectional view of the TMR element 30. As illustrated in FIG. 4, the TMR element 30 includes the substrate E1, the electrode layers 12 and 13, the base layer 1, the stacked portion MS illustrated in FIG. 1, and side walls 10W disposed outside the stacked portion MS between the base layer 1 and the electrode layers 12 and 13. The side wall 10W is made of an insulating material such as SiO₂ (silicon dioxide), SiNX (silicon nitride), Al₂O₃ (aluminum oxide), TiO (titanium oxide), TaOX (tantalum oxide), or AlSiO (aluminum silicate). The side wall 10W of the TMR element and other layers can be formed by a sputtering method. Chemical vapor deposition (CVD) methods may also be used to form an oxide layer and/or a nitride layer and/or an oxynitride layer of the TMR element.

In accordance with the TMR element 30 according to the present embodiment described above, since there are at least three layers (four layers in the basic embodiment of FIG. 2 and three layers in the modification of FIG. 3) in the base layer 1 or 1x and there are at least two interfaces (three interfaces X1, X2, and X3 in the basic embodiment of FIG. 2 and two interfaces X2 and X4 in the modification of FIG. 3) between two layers made of different materials. Thus, when the base layer 1 is formed, since layers formed on these interfaces are easily crystallized, crystallinity and flatness of the second metal nitride layer 1D which is an uppermost layer among the metal nitride layers of the base layer 1 are improved as compared with a case where the entire base layer 1 is made of only the material constituting the second metal nitride layer 1D. Thus, crystallinity and flatness of the layers constituting the stacked portion MS (see FIG. 1) formed on such a base layer 1 can be improved.

In addition, in the above-described embodiment, the metal nitride layer (first metal nitride layer 1B of FIG. 2 or third metal nitride layer 1A of FIG. 3) provided on the side of the metal oxynitride layer 1C close to the substrate E1, among the plurality of layers constituting the base layer 1 or 1x, is preferably the thickest. In this case, positions of some interfaces (interfaces X2 and X3 in FIG. 2 or interfaces X2 and X4 in FIG. 3) of the base layer 1 or 1x are close to the stacked portion MS (see FIG. 1). Thus, the above effect of improving the crystallinity and flatness of the layers constituting the stacked portion MS due to the presence of the interfaces X2, X3, and X4 is more effectively exhibited.

In addition, in the above-described embodiment, the first metal nitride layer 1B which is the metal nitride layer positioned in the middle in a thickness direction of the base layer 1, among the first metal nitride layer 1B, the second metal nitride layer 1D, and the third metal nitride layer 1A, is preferably the thickest (see FIG. 2). In this case, the positions of some interfaces X2 and X3 of the base layer 1 are close to the stacked portion MS (see FIG. 1). Thus, the above effect of improving the crystallinity and flatness of the layers constituting the stacked portion MS due to the presence of the interfaces X2 and X3 is more effectively exhibited.

In addition, in the above-described embodiment, the third metal nitride layer 1A which is the metal nitride layer provided closest to the substrate E1, among the plurality of metal nitride layers included in the base layer 1 or 1x, is preferably thicker than the metal oxynitride layer 1C (see FIGS. 2 and 3). In this case, the positions of the interfaces X1, X2, X3, and X4 of the base layer 1 or 1x are close to the stacked portion MS (see FIG. 1). Thus, the above effect of improving the crystallinity and flatness of the layers constituting the stacked portion MS due to the presence of these interfaces is more effectively exhibited.

In addition, in the above-described embodiment, the thickness of the base layer 1 or 1x is preferably 50 nm or more (see FIGS. 2 and 3). As a result, the above effect of improving the crystallinity and flatness of the layers constituting the stacked portion MS is particularly effectively exhibited. In addition, the thickness of the base layer 1 or 1x can be 100 nm or less.

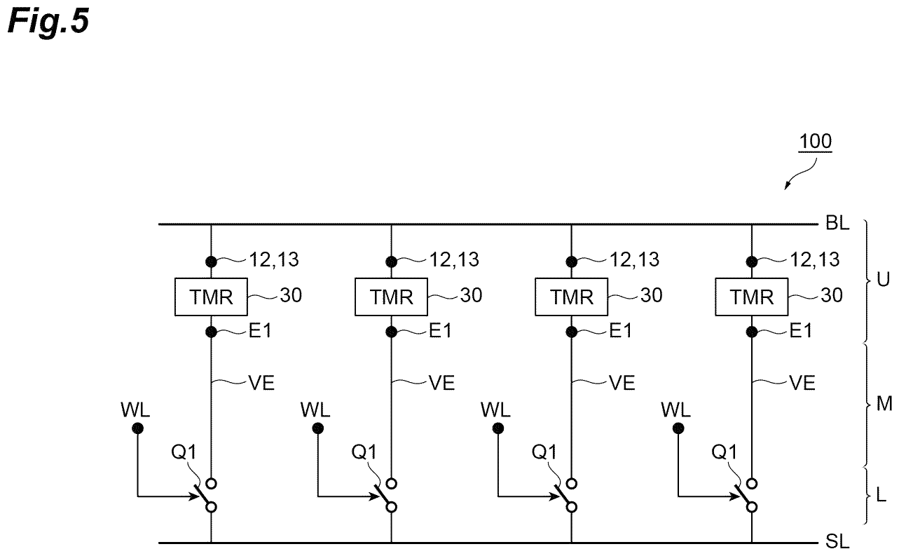

FIG. 5 is a diagram illustrating a circuit diagram of a magnetic memory 100. As illustrated in FIG. 5, the magnetic memory 100 includes a plurality of TMR elements 30. The TMR element 30 includes the elements illustrated in FIGS. 1 to 3 described above. The magnetic memory 100 is a spin-transfer torque magnetic random-access memory (STT-MRAM).

The magnetic memory 100 includes a lower portion L, an intermediate portion M, and an upper portion U. The lower portion L includes a semiconductor substrate having a plurality of transistors Q1 (switches). Drains of the transistors Q1 are connected to the substrates E1 of the TMR elements 30 with via electrodes VE interposed therebetween, respectively. Sources of the transistors Q1 are connected to a source line SL. The source line SL may be formed in the lower portion L or may be formed in the intermediate portion M. Gates of the transistors Q1 are connected to word lines WL, respectively.

The via electrodes VE and the word lines WL are formed in the intermediate portion M made of an insulating layer. In addition, the insulating layer is made of a material such as SiO₂, SiNX or Al₂O₃. The upper portion U is a portion positioned above the via electrodes VE.

The electrode layers 12 and 13 of the TMR elements 30 are connected to a bit line BL.

The transistor Q1 is turned on by a potential of the word line WL, and the TMR element 30 is selected. In addition, the bit line BL or the source line SL supplies a current to the selected TMR element 30. The STT-MRAM stores the magnetization direction of the magnetization free layer in response to a given current. Since the magnetic memory 100 includes the TMR element 30 in which the flatness and the crystallinity of the layers constituting the element are high as described above, reliability related to a lifespan and the like is enhanced.

In a case where data is written to a memory cell of the magnetic memory 100, a select voltage is applied to the word line WL corresponding to the TMR element 30 to be written. Then, in a state where the TMR element 30 is turned on, a voltage is applied between the bit line BL and the source line SL such that a current having a polarity corresponding to write data (“1” or “0”) flows. A magnitude of the voltage applied at this time is set to a magnitude that can cause spin injection magnetization reversal in the magnetization free layer 8 of the TMR element 30. Accordingly, the magnetization direction of the magnetization free layer 8 is set to a direction corresponding to the write data.

In a case where data is read from the memory cell of the magnetic memory 100, the select voltage is applied to the word line WL corresponding to the TMR element 30 to be read. Then, in a state where the TMR element 30 is set to an on state, a voltage smaller than the voltage at the time of writing is applied between the bit line BL and the source line SL. Accordingly, since a current having a magnitude corresponding to the data stored in the TMR element 30 flows between the bit line BL and the source line SL with the TMR element 30 interposed therebetween, a current value can be detected, and the data can be read.

The present disclosure is not limited to the above-described embodiment, and various modifications can be made.

For example, in the above-described embodiment, the metal constituting the second metal nitride layer 1D and the metal constituting the third metal nitride layer 1A are the same (see FIGS. 2 and 3), but these metals may be different from each other.

In addition, the magnetoresistive element of the above-described embodiment is the TMR element 30 (see FIG. 1), but the magnetoresistive element of the present disclosure may be a giant magnetoresistance (GMR) element. In this case, a layer made of a nonmagnetic conductive material such as Ag or Cu is used instead of the tunnel barrier layer 7 in the stacked portion MS.

The magnetoresistive element and the magnetic memory of the present disclosure have the following configurations.
[1] A magnetoresistive element including
a substrate,
a base layer provided on the substrate,
a stacked portion provided on the base layer, and including a magnetization free layer, a reference layer, and a nonmagnetic layer provided between the magnetization free layer and the reference layer,
in which the base layer includes two or more metal nitride layers and a metal oxynitride layer provided between a first metal nitride layer and a second metal nitride layer of the two or more metal nitride layers.
[2] The magnetoresistive element according to [1], in which a metal constituting the first metal nitride layer and a metal constituting the second metal nitride layer are different.
[3] The magnetoresistive element according to [1] or [2] further including a metal layer provided between the base layer and the stacked portion.
[4] The magnetoresistive element according to any one of [1] to [3], in which the reference layer includes a first ferromagnetic layer, a second ferromagnetic layer, and a nonmagnetic insertion layer provided between the first ferromagnetic layer and the second ferromagnetic layer such that the first ferromagnetic layer and the second ferromagnetic layer are exchange-coupled.
[5] The magnetoresistive element according to any one of [1] to [4], in which the first metal nitride layer is provided on a side of the metal oxynitride layer close to the substrate, the second metal nitride layer is provided on a side of the metal oxynitride layer close to the stacked portion, and the first metal nitride layer is thickest in the base layer.
[6] The magnetoresistive element according to any one of [1] to [5], in which the base layer further includes a third metal nitride layer as the two or more metal nitride layers, and a metal nitride layer positioned in the middle in a thickness direction of the base layer, among the first metal nitride layer, the second metal nitride layer, and the third metal nitride layer, is thickest.
[7] The magnetoresistive element according to any one of [1] to [6], in which a metal nitride layer provided closest to the substrate of the two or more metal nitride layers is thicker than the metal oxynitride layer.
[8] The magnetoresistive element according to any one of [1] to [7], in which a metal constituting the metal nitride layer closest to the stacked portion of the two or more metal nitride layers and a metal constituting the metal nitride layer closest to the substrate of the two or more metal nitride layers are the same.
[9] The magnetoresistive element according to any one of [1] to [8], in which a thickness of the base layer is 50 nm or more.
[10] A magnetic memory including a plurality of the magnetoresistive element according to any one of [1] to [9].

### REFERENCE SIGNS LIST

1 base layer
1A third metal nitride layer
1B first metal nitride layer
1C metal oxynitride layer
1D second metal nitride layer
1M metal layer.

1. A magnetoresistive element comprising:
a substrate;
a base layer provided on the substrate;
a stacked portion provided on the base layer, and including a magnetization free layer, a reference layer, and a nonmagnetic layer provided between the magnetization free layer and the reference layer, wherein
the base layer includes two or more metal nitride layers and a metal oxynitride layer provided between a first metal nitride layer and a second metal nitride layer of the two or more metal nitride layers.

2. The magnetoresistive element according to claim 1, wherein a metal constituting the first metal nitride layer and a metal constituting the second metal nitride layer are different.

3. The magnetoresistive element according to claim 2, further comprising: a metal layer provided between the base layer and the stacked portion.

4. The magnetoresistive element according to claim 3, wherein the reference layer includes a first ferromagnetic layer, a second ferromagnetic layer, and a nonmagnetic insertion layer provided between the first ferromagnetic layer and the second ferromagnetic layer such that the first ferromagnetic layer and the second ferromagnetic layer are exchange-coupled.

5. The magnetoresistive element according to claim 4, wherein the first metal nitride layer is provided on a side of the metal oxynitride layer close to the substrate, the second metal nitride layer is provided on a side of the metal oxynitride layer close to the stacked portion, and the first metal nitride layer is thickest in the base layer.

6. The magnetoresistive element according to claim 4, wherein the base layer further includes a third metal nitride layer as the two or more metal nitride layers, and a metal nitride layer positioned in the middle in a thickness direction of the base layer, among the first metal nitride layer, the second metal nitride layer, and the third metal nitride layer, is thickest.

7. The magnetoresistive element according to claim 5, wherein a metal nitride layer provided closest to the substrate of the two or more metal nitride layers is thicker than the metal oxynitride layer.

8. The magnetoresistive element according to claim 5, wherein a metal constituting the metal nitride layer closest to the stacked portion of the two or more metal nitride layers and a metal constituting the metal nitride layer closest to the substrate of the two or more metal nitride layers are the same.

9. The magnetoresistive element according to claim 6, wherein a thickness of the base layer is 50 nm or more.

10. A magnetic memory comprising a plurality of the magnetoresistive element according to claim 1.

11. The magnetoresistive element according to claim 1, wherein a metal nitride layer provided closest to the substrate of the two or more metal nitride layers is thicker than the metal oxynitride layer.

12. The magnetoresistive element according to claim 2, wherein a metal nitride layer provided closest to the substrate of the two or more metal nitride layers is thicker than the metal oxynitride layer.

13. The magnetoresistive element according to claim 3, wherein a metal nitride layer provided closest to the substrate of the two or more metal nitride layers is thicker than the metal oxynitride layer.

14. The magnetoresistive element according to claim 4, wherein a metal nitride layer provided closest to the substrate of the two or more metal nitride layers is thicker than the metal oxynitride layer.

15. The magnetoresistive element according to claim 6, wherein a metal nitride layer provided closest to the substrate of the two or more metal nitride layers is thicker than the metal oxynitride layer.

16. The magnetoresistive element according to claim 1, wherein a metal constituting the metal nitride layer closest to the stacked portion of the two or more metal nitride layers and a metal constituting the metal nitride layer closest to the substrate of the two or more metal nitride layers are the same.

17. The magnetoresistive element according to claim 3, wherein a metal constituting the metal nitride layer closest to the stacked portion of the two or more metal nitride layers and a metal constituting the metal nitride layer closest to the substrate of the two or more metal nitride layers are the same.

18. The magnetoresistive element according to claim 4, wherein a metal constituting the metal nitride layer closest to the stacked portion of the two or more metal nitride layers and a metal constituting the metal nitride layer closest to the substrate of the two or more metal nitride layers are the same.

19. The magnetoresistive element according to claim 6, wherein a metal constituting the metal nitride layer closest to the stacked portion of the two or more metal nitride layers and a metal constituting the metal nitride layer closest to the substrate of the two or more metal nitride layers are the same.

20. The magnetoresistive element according to claim 7, wherein a metal constituting the metal nitride layer closest to the stacked portion of the two or more metal nitride layers and a metal constituting the metal nitride layer closest to the substrate of the two or more metal nitride layers are the same.
